(19) United States
(12) Patent Application Publication
(10) Pub. No.: US 2012/0194288 A1
(43) Pub. Date: Aug. 2, 2012

(54) Two-Terminal Modulator

(76) Inventor: Barry M. Laxton, Unionville (CA)

(21) Appl. No.: 13/353,810

(22) Filed: Jan. 19, 2012

Related U.S. Application Data
(60) Provisional application No. 61/436,936, filed on Jan. 27, 2011.

(51) Int. Cl. H03K 7/00

(52) U.S. Cl. 332/106

(57) ABSTRACT

The invention is an electronic Two-Terminal Modulator. It is used electrically in series between a Power Source and a Target Device, and can modulate the power that is sent to the Target Device, at speeds and with modulating complexity that exceed present capability. The invention includes implementation of the modulator as a unit that is inserted into or appended to another device and is used to modulate the power in the other device.

### BACKGROUND OF THE INVENTION

The example used is that of a laser diode powered by a battery. In the left side of FIG. 1, the laser diode is powered by the battery, but the power is not modulated, so the laser diode emits a steady light beam. Where it is desired that the laser diode emit a pulsing or otherwise modulated light beam, it is necessary to modulate the power that is sent to the laser diode.

One way to modulate the power is to insert a three-terminal modulating device into the circuit as shown in the example on the right side of FIG. 1. The three-terminal modulator is so-named because it connects to the other components of the circuit in three places (“terminals”), labelled A, B and C.

There are situations where it is inconvenient or impossible to insert a three-terminal modulator into a circuit. A Two-Terminal Modulator is shown in FIG. 2. It is so-named because it connects to the other components of the circuit in only two places, labelled D & E.

Two-Terminal Modulators have been implemented in a variety of ways, often using heaters and bi-metallic strips to flash ornamental light bulbs, but they are limited in speed and in the complexity of the modulation.

### BRIEF SUMMARY OF THE INVENTION

The invention is an electronic Two-Terminal Modulator. It is used electrically in series between a Power Source and a Target Device, and can modulate the power that is sent to the Target Device, at speeds and with modulating complexity that exceed present capability.

The invention includes implementation of the Two-Terminal Modulator as a unit that is inserted into a battery compartment of an existing device and used to modulate the power in the other device.

### BRIEF DESCRIPTION OF THE SEVERAL VIEWS OF THE DRAWING

FIG. 1. Comparison of Not-Modulated and Modulated Laser Diode

FIG. 2. Two-Terminal Modulator in Use

FIG. 3. Two-Terminal Modulator Block Diagram

FIG. 4. Use of Two-Terminal Modulator inside Battery Compartment

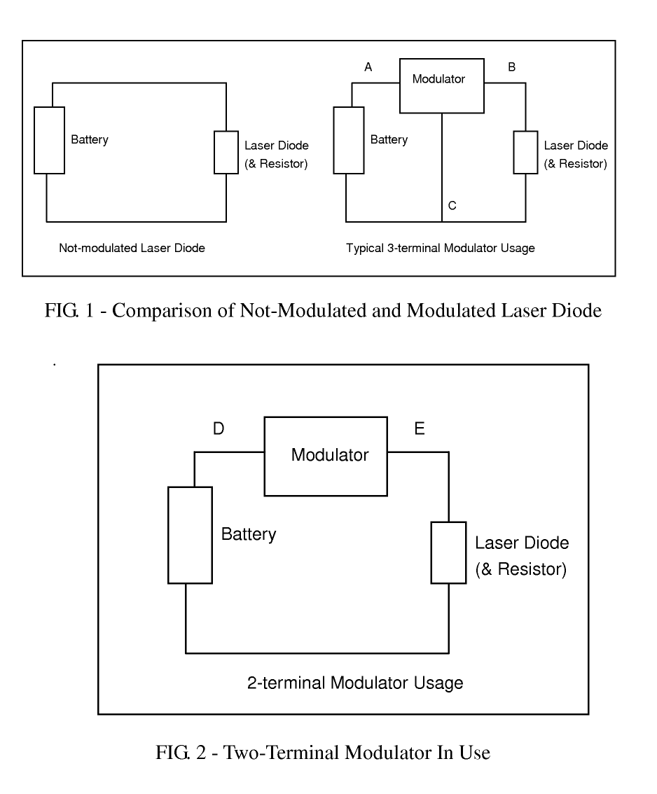

### DETAILED DESCRIPTION OF THE INVENTION

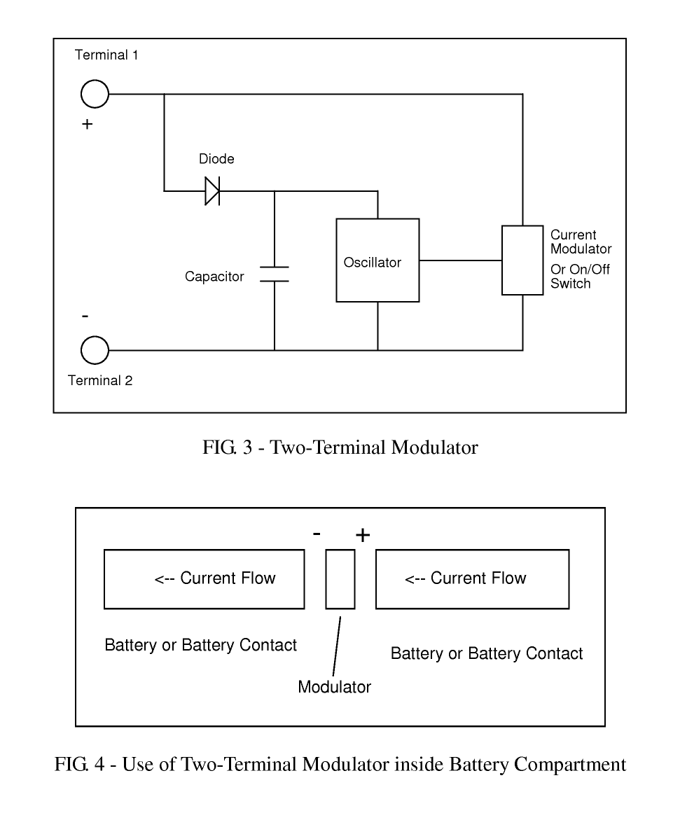

The invention is detailed in FIG. 3. Initially, the Capacitor starts to charge until it has enough voltage to operate the Oscillator. The Current Modulator or On/Off Switch is controlled by the Oscillator, and eventually starts passing current through itself and therefore from Terminal 1 to Terminal 2.

At times, during normal operation, the Current Modulator or On/Off Switch is passing all or most of the current passing through the Target Device, so insufficient current is available to power the Oscillator. At these times the Diode isolates the Capacitor from the input power and the Capacitor supplies the current that keeps the Oscillator running.

The invention can be implemented as a sufficiently-small separate stand-alone unit that is inserted into a battery compartment in series with the battery to easily convert an existing unmodulated device into a modulated device, as shown in FIG. 4.

The Two-Terminal Modulator is constructed using standard electronic methodologies.

This is a non-provisional application of provisional patent U.S. 61/436,936 filed on Jan. 27, 2011 and I claim all rights:

1. Embodiments and embellishments of the electronic structure shown in FIG. 3.

2. A device that embodies the electronic structure shown in FIG. 3 as a unit that is to be inserted into or appended to a second electronic unit for the purpose of modulating the power used within the second electronic unit.
